(19) United States
(12) Patent Application Publication
(10) Pub. No.: US 2018/0102792 A1
(43) Pub. Date: Apr. 12, 2018

(54) JOINT DETECTOR/ DECODER DEVICES AND JOINT DETECTION/ DECODING METHODS

(71) Applicant: Agency for Science, Technology and Research, Singapore (SG)

(72) Inventors: Kheong Sann Chan, Singapore (SG); Ashish James, Singapore (SG)

(21) Appl. No.: 15/568,866

(22) PCT Filed: May 5, 2016
(86) PCT No.: PCT/SG2016/050207

§ 371 Date: Oct. 24, 2017

(30) Foreign Application Priority Data
May 5, 2015 (SG) 10201503509U

(51) Int. Cl. H03M 13/41; H03M 13/29; H03M 13/00; H04L 1/00; H04L 25/03

(52) U.S. Cl. CPC H03M 13/41; H03M 13/29; H03M 13/6325; G11B 2020/1863; H04L 25/03235; H04L 1/0054; H04L 1/006; H04L 1/005

(57) ABSTRACT

According to various embodiments, a joint detector/decoder device may be provided. The joint detector/decoder device may include: an input circuit configured to receive an input signal; a splitting determination circuit configured to determine whether a survivor is to be split based on a parity check criterion; and a survivor splitting circuit configured to produce a plurality of survivors of a next instance based on at least one survivor of a previous instance and based on the input signal, if it is determined that the survivor of the previous instance is to be split; wherein each survivor has an associated bit sequence.

### CROSS-REFERENCE TO RELATED APPLICATIONS

The present application claims the benefit of the Singapore patent application No. 10201503509U filed on 5 May 2015, the entire contents of which are incorporated herein by reference for all purposes.

### TECHNICAL FIELD

Embodiments relate generally to joint detection/decoder devices and joint detection/decoding methods.

### BACKGROUND

Detection and decoding of a received signal is a task that is performed in every receiver. Thus, there may be a need for efficient detection and efficient decoding.

### SUMMARY

According to various embodiments, a joint detector/decoder device may be provided. The joint detector/decoder device may include: an input circuit configured to receive an input signal; a splitting determination circuit configured to determine whether a survivor is to be split based on a parity check criterion; and a survivor splitting circuit configured to produce a plurality of survivors of a next instance based on at least one survivor of a previous instance and based on the input signal, if it is determined that the survivor of the previous instance is to be split; wherein each survivor has an associated bit sequence.

According to various embodiments, a joint detection/decoding method may be provided. The joint detection/decoding method may include: receiving an input signal; determining whether a survivor is to be split based on a parity check criterion; and producing a plurality of survivors of a next instance based on at least one survivor of a previous instance and based on the input signal, if it is determined that the survivor of the previous instance is to be split; wherein each survivor has an associated bit sequence.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A and FIG. 1B show joint detector/decoder devices according to various embodiments;

FIG. 1C shows a joint detector/decoder device according to various embodiments;

FIG. 2 shows a communication system block diagram according to various embodiments;

FIG. 3 shows a joint Viterbi detector decoder (JVDD) trellis that is divided into two sections. In the metric thresholding section, channel bits are detected in a similar fashion to the regular Viterbi algorithm, wherein metrics are computed and survivors with larger metrics are discarded. In the parity checking section, additional computations are performed whenever the bit corresponding to the last one in any row of the parity check matrix H is detected, the parity check for each survivor is evaluated, and the survivors violating the parity checks are discarded. Thus only survivors corresponding to legal codewords make it through at the end of the trellis;

FIG. 4A to FIG. 4K show the evolution of MP-JVDD in the trellis with the current parity check constraint highlighted by a rectangle with arrows pointing at where splitting occurs in the MP-JVDD trellis corresponding to a 1 in the parity check constraint;

FIG. 4L to FIG. 4P further illustrate the splitting happening in MP-JVDD trellis only at those parity check nodes where it hasn't split before;

FIG. 5A and FIG. 5B show the comparison of JVDD (FIG. 5A) and MP-JVDD (FIG. 5B) for the number of survivors propagating through the trellis;

FIG. 6 depicts the parity check matrix H based on variable-gradient Gaussian distributed linear diagonal codes for codeword length of 512 and 0.5 rate. 1's are represented as black dots while white spaces represent 0 in this figure;

FIG. 7A and FIG. 7B show comparisons of the FER (frame error rate) performance of MP-JVDD and JVDD with complexity for codeword lengths 64 (FIG. 7A) and 128 (FIG. 7B) at different rates;

FIG. 8A and FIG. 8B show comparisons of the FER performance of iterative BCJR/SPA decoder, JVDD and MP-JVDD at different signal-to-noise ratios and for codeword lengths 64 (FIG. 8A) and 128 (FIG. 8B);

FIG. 9A and FIG. 9B show illustrations of the FER performance of MP-JVDD and JVDD with complexity for codeword lengths 256 (FIG. 9A) and 512 (FIG. 9B) at different SNRs;

FIG. 10A and FIG. 10B show illustrations of FER comparisons with complexity of JVDD algorithm at different rates; and

FIG. 11 shows an illustration of an output of Viterbi algorithm.

### DESCRIPTION

Embodiments described below in context of the devices are analogously valid for the respective methods, and vice versa. Furthermore, it will be understood that the embodiments described below may be combined, for example, a part of one embodiment may be combined with a part of another embodiment.

In this context, the joint detection/decoder device as described in this description may include a memory which is for example used in the processing carried out in the joint detection/decoder device. A memory used in the embodiments may be a volatile memory, for example a DRAM (Dynamic Random Access Memory) or a non-volatile memory, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory).

In an embodiment, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail below may also be understood as a “circuit” in accordance with an alternative embodiment.

Various embodiments relate to detection and decoding of information transmitted over a coded digital communication system with inter-symbol interference (ISI) and may provide a general framework for the joint detection and decoding of information within such systems.

Data communication systems have been under continual development over the years and the strong demand for reliable high rate transmission ranges from magnetic recording to wireless communications systems. In the aforementioned fields of application, one of the major obstacles to achieve capacity is inter-symbol interference (ISI) which is a form of distortion in which the signals from neighboring symbols interfere with each other on retrieval. To mitigate the interference and recover the transmitted signals at the receiver, typically trellis-based algorithms such as the Viterbi detector are used. It is well recognized that significant performance improvement can be obtained by integrating detection algorithms with channel coding techniques. One such method that offers significant performance improvement is iterative detection-decoding (IDD) based on the Turbo principle, i.e., exchanging (extrinsic) information between an inner detector and an outer channel decoder. Despite the success of this approach there are several open issues for such an IDD scheme, e.g. severe detection/decoding delay especially for codes with short block lengths, or prohibitively high computational complexity associated with IDD systems in general. Furthermore, it has a performance gap to the optimal maximum-likelihood (ML) decoder for any code-structure.

Maximum-likelihood decoders have been analyzed over different communication channels—additive white Gaussian noise (AWGN), binary symmetric channel (BSC), binary erasure channel (BEC) among others. These have also been employed for two broad classes of codes namely block codes and convolutional codes. With convolutional codes, efficient trellis based algorithm known as Viterbi algorithm (VA) can be employed to perform ML decoding and return the most probable transmitted codeword. However, optimal ML decoding of linear block codes has been proven to be an NP-hard problem, whose complexity grows exponentially as the code length increases. There have been many research efforts in this direction to develop optimal or suboptimal decoding algorithms with moderate complexity.

The joint Viterbi detector decoder (JVDD) has been introduced as an alternative optimal detection and decoding scheme that attempts to return the minimum metric legal codeword (MMLC). The JVDD operates on a trellis and has a two-stage decoding structure—metric thresholding and parity checking. The first stage executes the normal Viterbi algorithm (VA) by computing metrics for every possible path to a node. However, the JVDD retains the minimum metric survivor along with a certain number of competing paths in the trellis constrained by a threshold parameter. Thus only survivors with metrics within the threshold of the minimum metric for a particular node are retained. This would typically mean setting a larger threshold to minimize the probability of discarding the MMLC. However, this leads to a larger number of survivors resulting in an increased complexity.

According to various embodiments, the complexity may be reduced by performing parity checking on each incoming survivor path and discarding those which fail the syndrome check i.e., cH^{T}=0, where c is the codeword and H is the parity check matrix. This parity checking section provides a system tradeoff design between complexity and code-rate. The JVDD algorithm is conditionally optimal with the condition being sufficiency of computational resources.

Various embodiments may be a modification on the previously proposed JVDD algorithm coined the multi-pass JVDD (MP-JVDD). The main drawback of the JVDD, is the large number of survivors needed in the trellis in order to have an acceptable probability of error. This large number of survivors translates into large memory and computing requirements for the algorithm. The MP-JVDD may be provided in order to cut-down the number of survivors needed in the algorithm.

The JVDD works by keeping a large number of possible survivors in the initial part of the algorithm (the metric thresholding) to be checked in the latter part of the algorithm (the parity checking). Splitting of survivors occurs at every node in the JVDD.

In contrast, the MP-JVDD according to various embodiments keeps fewer survivors, and attempts to get past each parity check node one at a time. To achieve this, splitting only needs to happen at the particular nodes involved in the current parity check, as opposed to splitting at every node for the JVDD. This reduces the number of survivors in the trellis. However, it has to be repeated for every parity check in H. Herein lies the multi-pass nature of the algorithm. It repeats one pass per parity check node (of which there are m). Each pass has substantially fewer survivors, since splits no longer occur at every node. This results in lower memory and computational requirements for the algorithm. However the multi-pass nature could end up introducing algorithm latency. Further optimization work is required on the codes for JVDD which will determine the ultimate performance/complexity trade-off of this algorithm.

According to various embodiments, a multi-pass joint Viterbi detector decoder (MP-JVDD) may be provided.

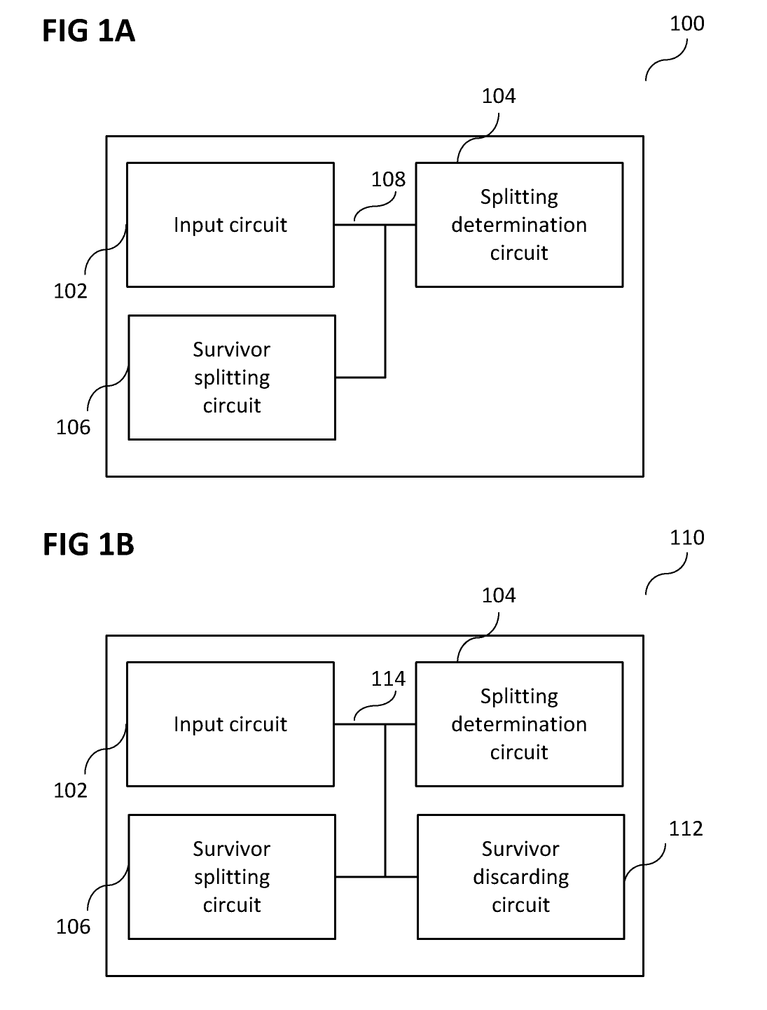

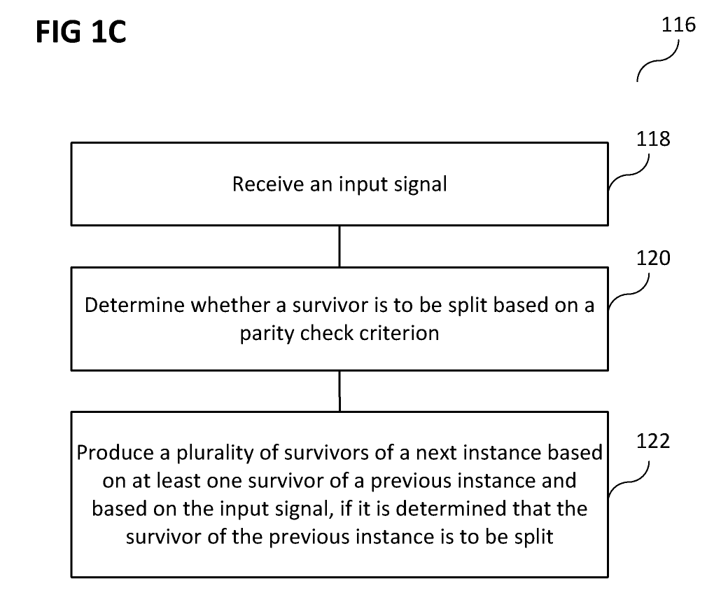

FIG. 1A shows a joint detector/decoder device 100 according to various embodiments. The joint detector/decoder device 100 may include an input circuit 102 configured to receive an input signal. The joint detector/decoder device 100 may further include a splitting determination circuit 104 configured to determine whether a survivor is to be split based on a parity check criterion. The joint detector/decoder device 100 may further include a survivor splitting circuit configured to produce a plurality of survivors of a next instance based on at least one survivor of a previous instance and based on the input signal, if it is determined that the survivor of the previous instance is to be split. Each survivor may have an associated bit sequence. The input circuit 102, the splitting determination circuit 104, and the survivor splitting circuit 106 may be (electrically) coupled with each other, like indicated by lines 108.

In other words, in a JVDD, splitting may be performed only if a parity check criterion is fulfilled.

FIG. 1B shows a joint detector/decoder device 110 according to various embodiments. The joint detector/decoder device 110 may, similar to the joint detector/decoder device 100 of FIG. 1A, include an input circuit 102 configured to receive an input signal. The joint detector/decoder device 110 may, similar to the joint detector/decoder device 100 of FIG. 1A, further include a splitting determination circuit 104 configured to determine whether a survivor is to be split based on a parity check criterion. The joint detector/decoder device 110 may, similar to the joint detector/decoder device 100 of FIG. 1A, further include a survivor splitting circuit configured to produce a plurality of survivors of a next instance based on at least one survivor of a previous instance and based on the input signal, if it is determined that the survivor of the previous instance is to be split. The joint detector/decoder device 110 may further include a survivor discarding circuit 112, like will be described in more detail below. Each survivor may have an associated bit sequence. The input circuit 102, the splitting determination circuit 104, the survivor splitting circuit 106, and the survivor discarding circuit 112 may be (electrically) coupled with each other, like indicated by lines 114.

According to various embodiments, the survivor discarding circuit 112 may be configured to discard survivors based on a set of predetermined criteria.

According to various embodiments, a survivor determination circuit including the survivor splitting circuit 106 and the survivor discarding circuit 112 may be configured to determine that a survivor survives to the next instance if the metric of the survivor is within a pre-determined metric threshold.

According to various embodiments, the joint detector/decoder device 110 may be configured to retain a predetermined set of survivors with the smallest metrics as the plurality of survivors of the next instance.

According to various embodiments, the pre-determined validity criterion may include or may be a parity check based on whether the survivor's bit pattern satisfies the checks of a parity check matrix.

According to various embodiments, the parity check matrix may include a matrix with entries of zero above a pre-determined sub-diagonal of the parity check matrix.

According to various embodiments, the metric may include or may be an Euclidean metric.

FIG. 1C shows a flow diagram 116 illustrating a joint detection/decoding method according to various embodiments. In 118, an input signal may be received. In 120, it may be determined whether a survivor is to be split based on a parity check criterion. In 122, a plurality of survivors of a next instance may be produced based on at least one survivor of a previous instance and based on the input signal, if it is determined that the survivor of the previous instance is to be split. Each survivor may have an associated bit sequence.

According to various embodiments, the joint detection/decoding method may further include discarding survivors based on a set of predetermined criteria;

According to various embodiments, the joint detection/decoding method may further include determining that a survivor survives to the next instance if the metric of the survivor is within a pre-determined metric threshold.

According to various embodiments, the joint detection/decoding method may further include retaining a predetermined number of survivors with the smallest metrics as the plurality of survivors of the next instance.

According to various embodiments, the pre-determined validity criterion may include or may be a parity check based on whether the survivor's bit pattern satisfies the checks of a parity check matrix.

According to various embodiments, the parity check matrix may include or may be a matrix with entries of zero above a pre-determined sub-diagonal of the parity check matrix.

According to various embodiments, the joint detection/decoding method may further include determining, during a metric thresholding section, whether a survivor carries on to the next instance based on a metric of the bit sequence and independent from whether the bit sequence fulfills a pre-determined validity criterion.

According to various embodiments, the joint detection/decoding method may further include determining, during a parity check section, whether a survivor carries on to the next instance based on a metric of the bit sequence and based on whether the bit sequence fulfills a pre-determined validity criterion.

According to various embodiments, the metric may include or may be an Euclidean metric.

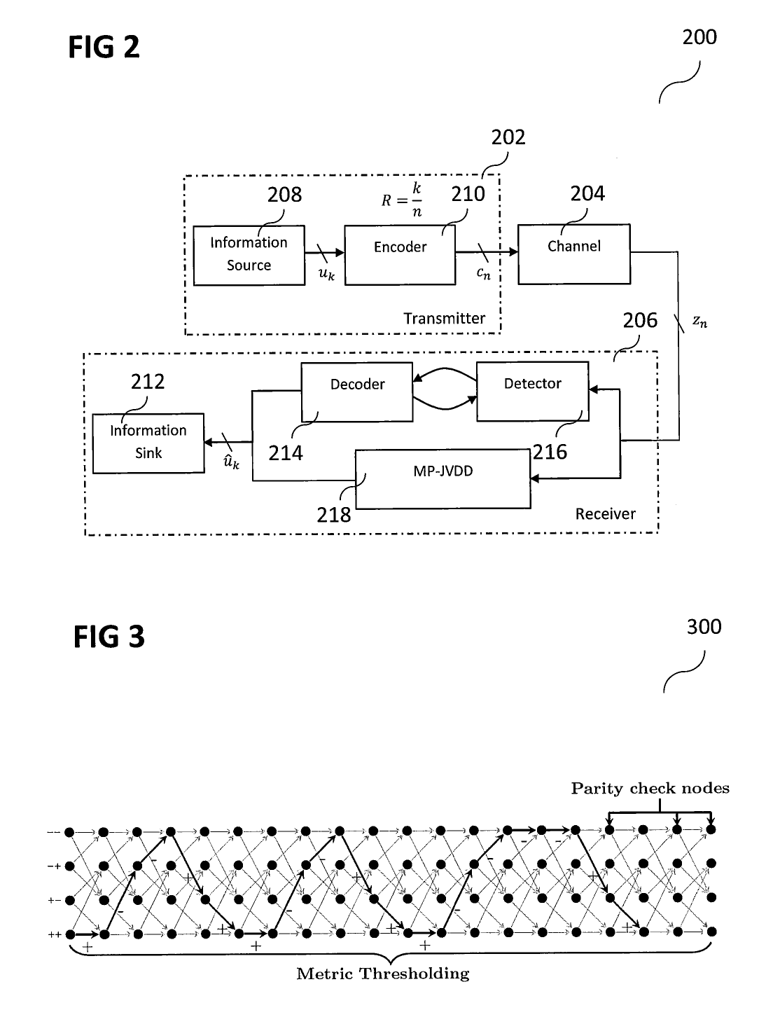

FIG. 2 shows an illustration 200 of a data communication block diagram according to various embodiments with the MP-JVDD 218 at the receiver 206. In a transmitter, an information source 208 provides information to an encoder 210. The encoded information is transmitted via a channel 204 to the receiver 206, to finally arrive at an information sink 212. The competing iterative detectors 216 and decoders 214 are also illustrated in FIG. 2, where the conventional detector is based on a soft-output detector such as soft output Viterbi algorithm (SOVA) or the Bahl, Cocke, Jelinek, Raviv (BCJR) algorithm which is run over a trellis followed by the decoder based on sum product algorithm which runs on a factor graph. Despite the success of the aforementioned approach, it has a performance gap with the optimal maximum likelihood (ML) decoder for any code-structure. This motivates the search for schemes that have a chance of achieving optimality and according to various embodiments, joint detection/decoding is a promising candidate. However, optimal ML (maximum likelihood) decoding of linear block codes has been proven to be an NP-hard problem, whose complexity grows exponentially as the codeword length (CWL) increases. There have been many research efforts in this direction to develop optimal or suboptimal decoding algorithms with moderate complexity.

In a previous example, joint Viterbi detector decoder has been introduced as an alternative optimal ML detection and decoding scheme that attempts to return the minimum metric legal codeword (MMLC). It operates on a trellis and has a two-stage decoding structure—metric thresholding and parity checking as shown in illustration 300 of FIG. 3. The first stage executes the normal Viterbi algorithm (VA) by computing metrics for every possible path to a node. At each step, existing survivors is split into 2 new survivors, obtained by appending a + and − respectively and the corresponding metrics are computed. However, the JVDD retains the minimum metric survivor (similar to VA) along with certain number of competing paths in the trellis constrained by a threshold parameter. Thus only survivors with metrics within the threshold of the minimum metric for a particular node are retained. This would typically mean setting a larger threshold to minimize the probability of discarding the MMLC. However, this leads to a larger number of survivors resulting in an increased complexity.

According to various embodiments, metric thresholding may include computing path metric for survivors (which may be similar or the same as Viterbi), and survivors whose metrics are smaller than a threshold may be retained. Larger threshold may reduce probability of discarding MMLC, but may lead to increased complexity.

According to various embodiments, parity checking may include discarding survivors that fail syndrome check: cH^{T}≠0, wherein H is an m×n parity check matrix, m is the number of rows, corresponding to the number of parity checks, and n is the number of cols (columns), corresponding to the number of coded bits.

According to various embodiments, the complexity is reduced by performing parity checking on each incoming survivor path and discarding those which fail the syndrome check i.e., cH^{T}=0, where c is the codeword and H is the parity check matrix. This parity checking section provides a system tradeoff design between complexity and code-rate.

The JVDD algorithm is conditionally optimal with the condition being sufficiency of computational resources. In order to reduce the computational complexity of JVDD a modification to the algorithm coined the multi-pass JVDD (MP-JVDD) is developed. The MP-JVDD according to various embodiments operates on a trellis, performing both detection and decoding in two stages. The first stage executes the usual Viterbi algorithm which finds the path along the trellis that has the smallest Euclidean distance from the sequence observed at the receiver. At every time, say from time t to (t+1), each of the existing survivors are split into 2 new survivors. This is obtained by appending a + and −, corresponding to the bits 1 and 0, respectively. The corresponding metrics (branch and path metrics) are computed and then retains only the minimum (path) metric survivor at each state for each time-step. Basically, this process doubles and then halves the number of survivors at each step. This computation proceeds till the algorithm reaches the termination node (the all-zero state), at which time it returns the minimum metric sequence corresponding to the maximum-likelihood path. However, the minimum metric sequence might not correspond to the minimum metric legal codeword (MMLC). This is ensured in MP-JVDD through the second stage processing.

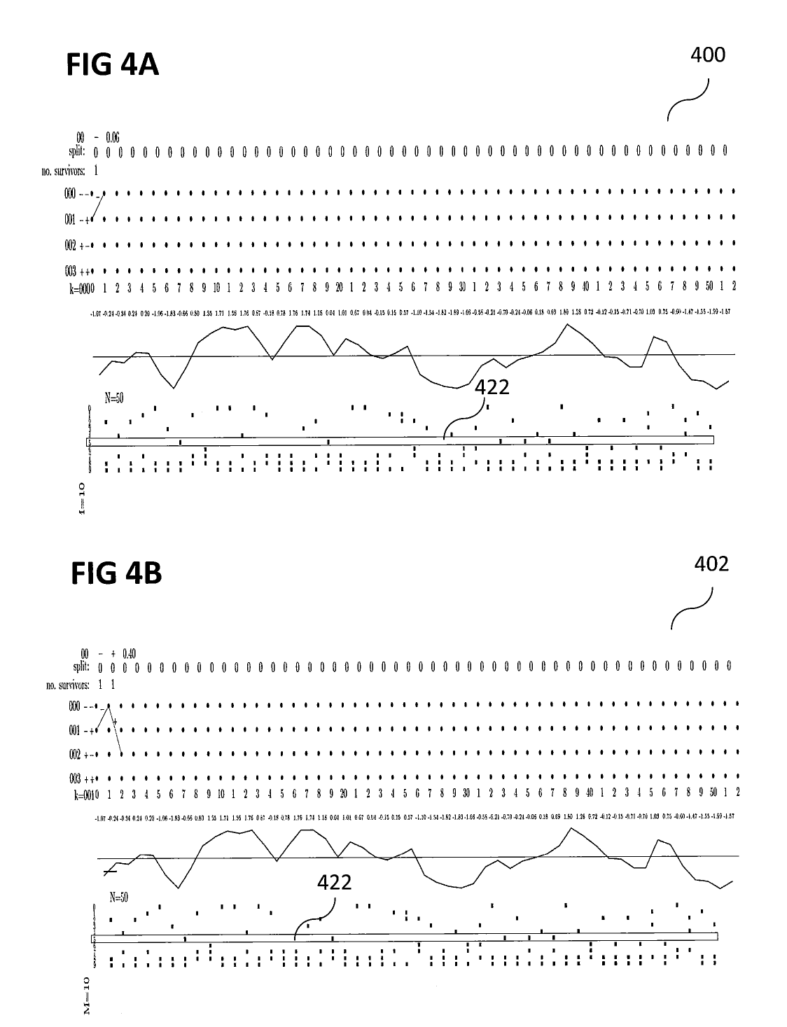

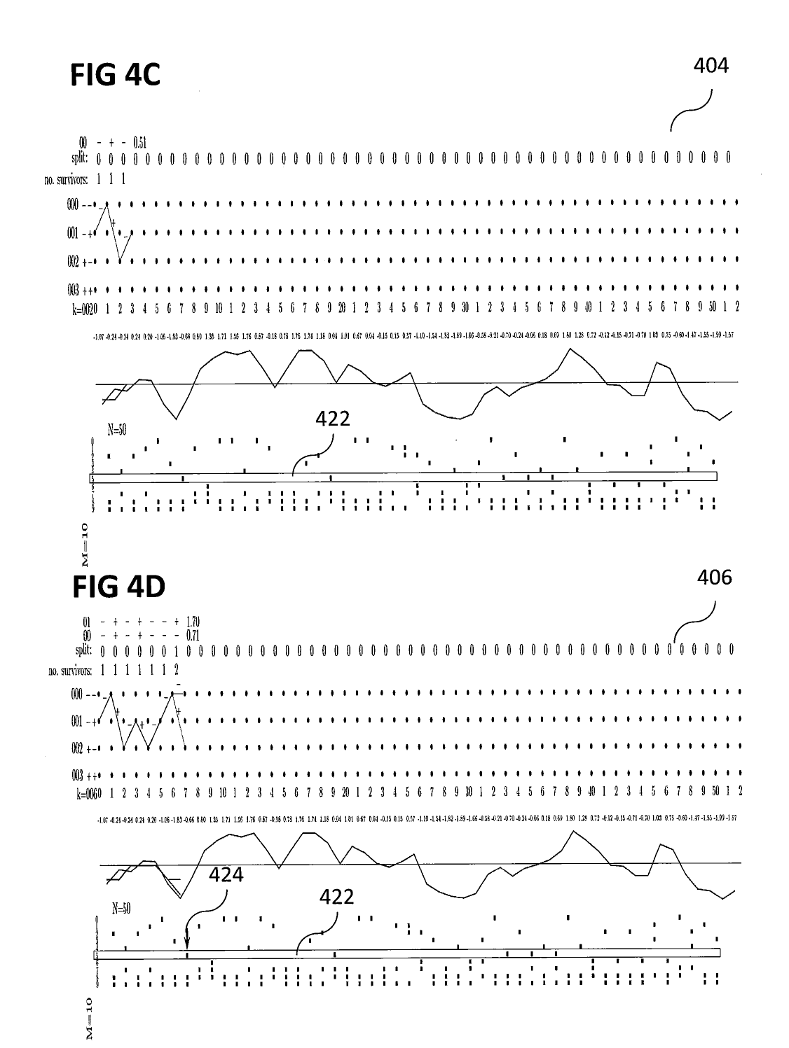

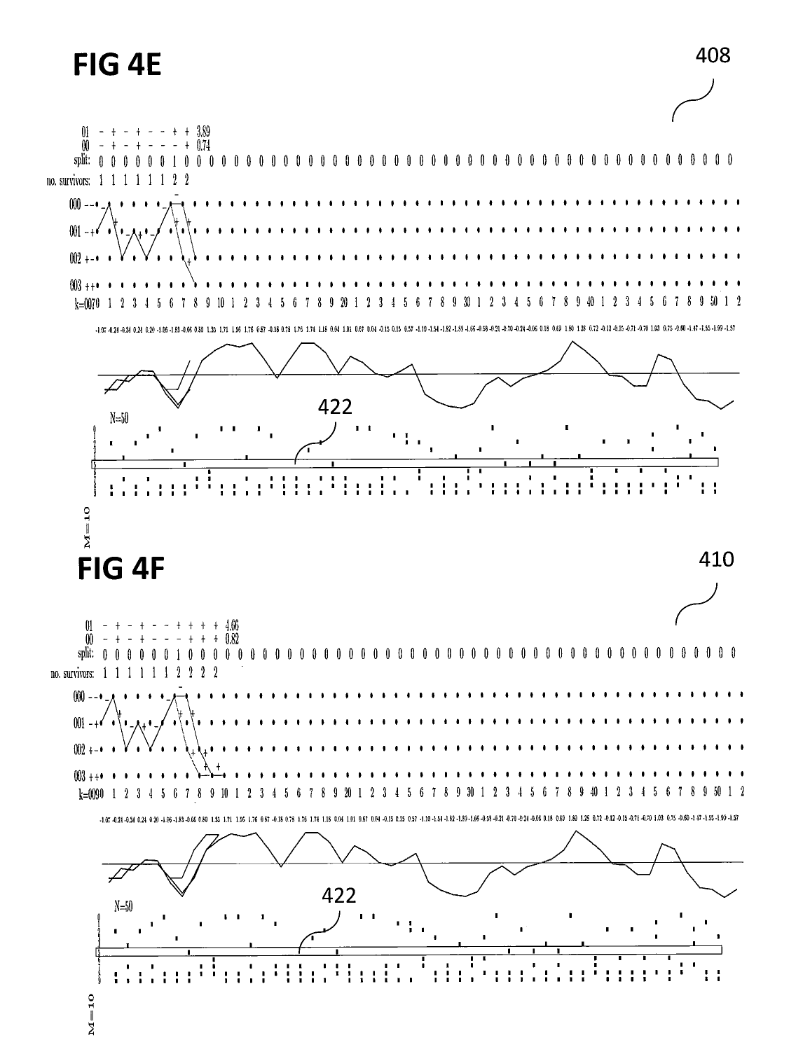

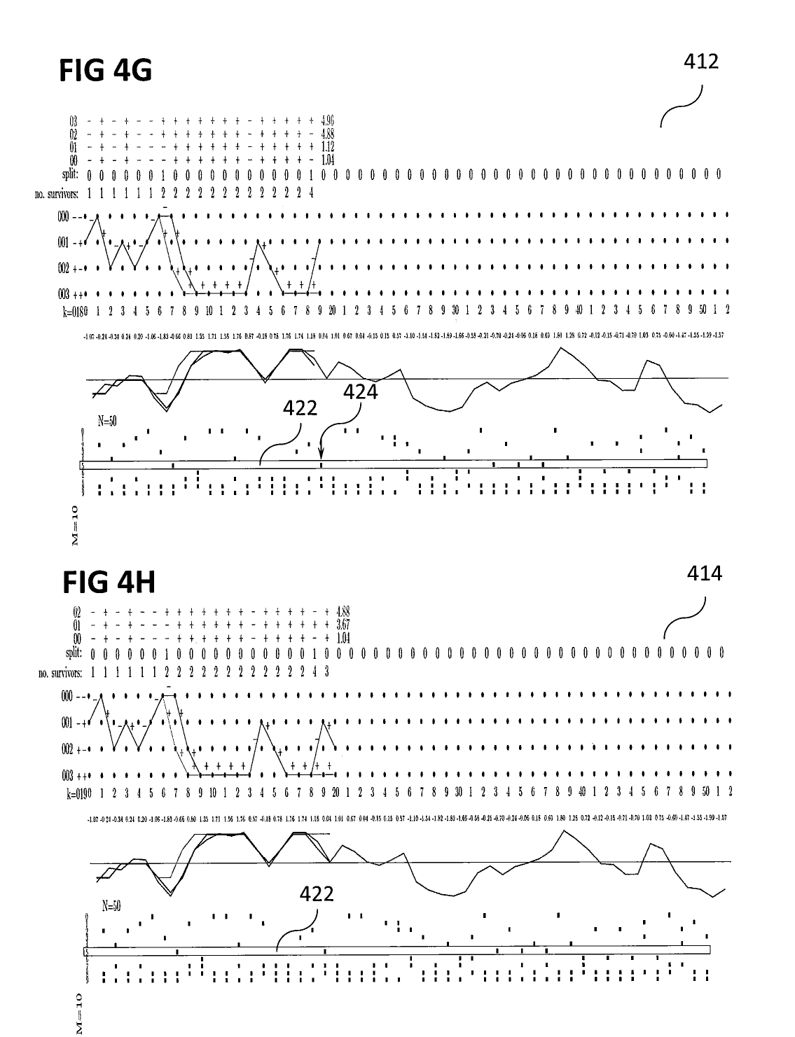

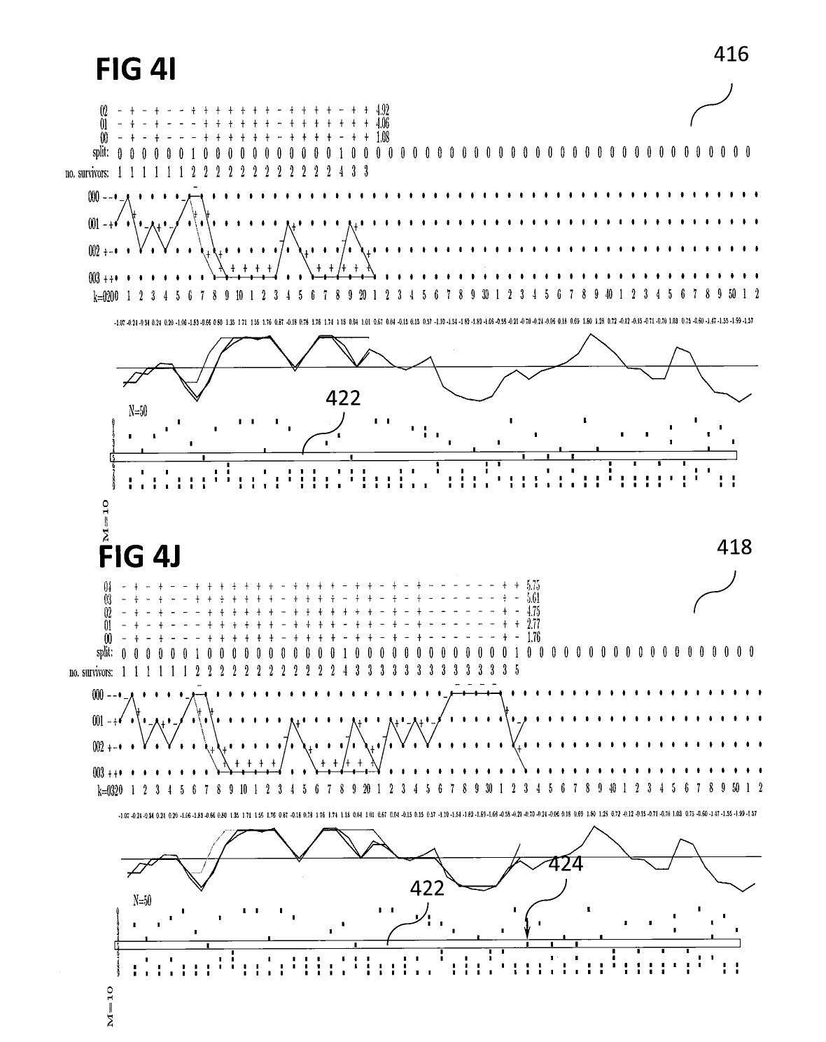

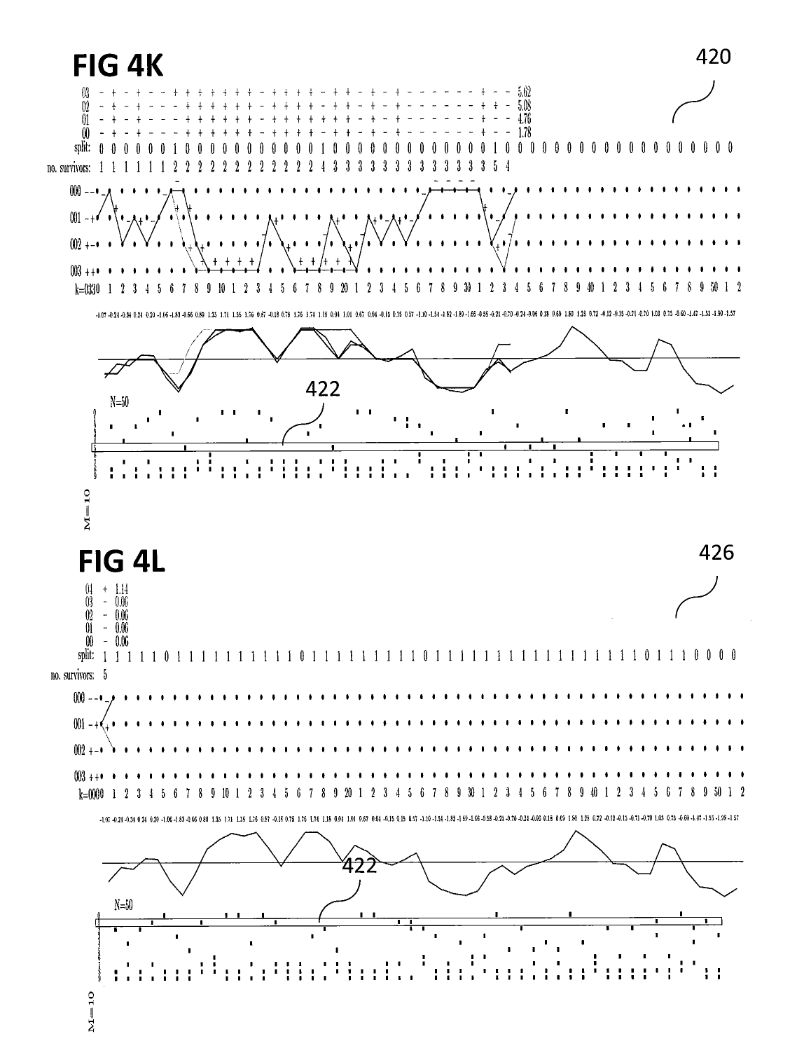

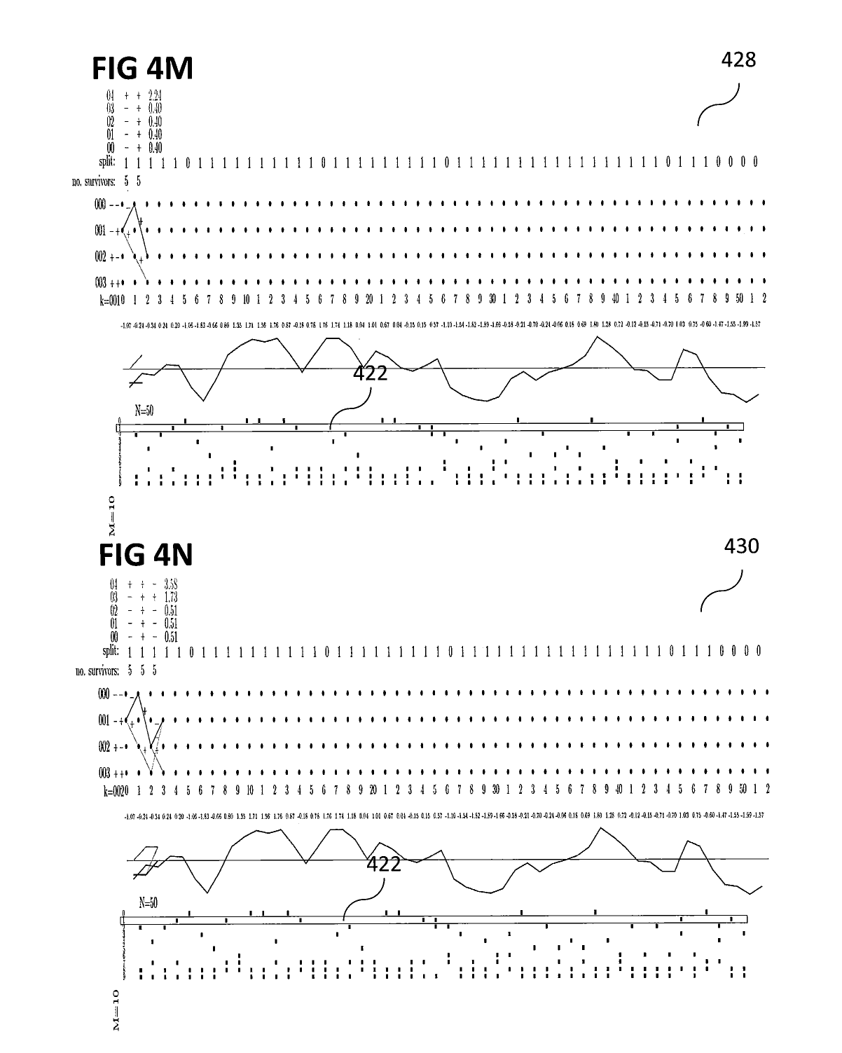

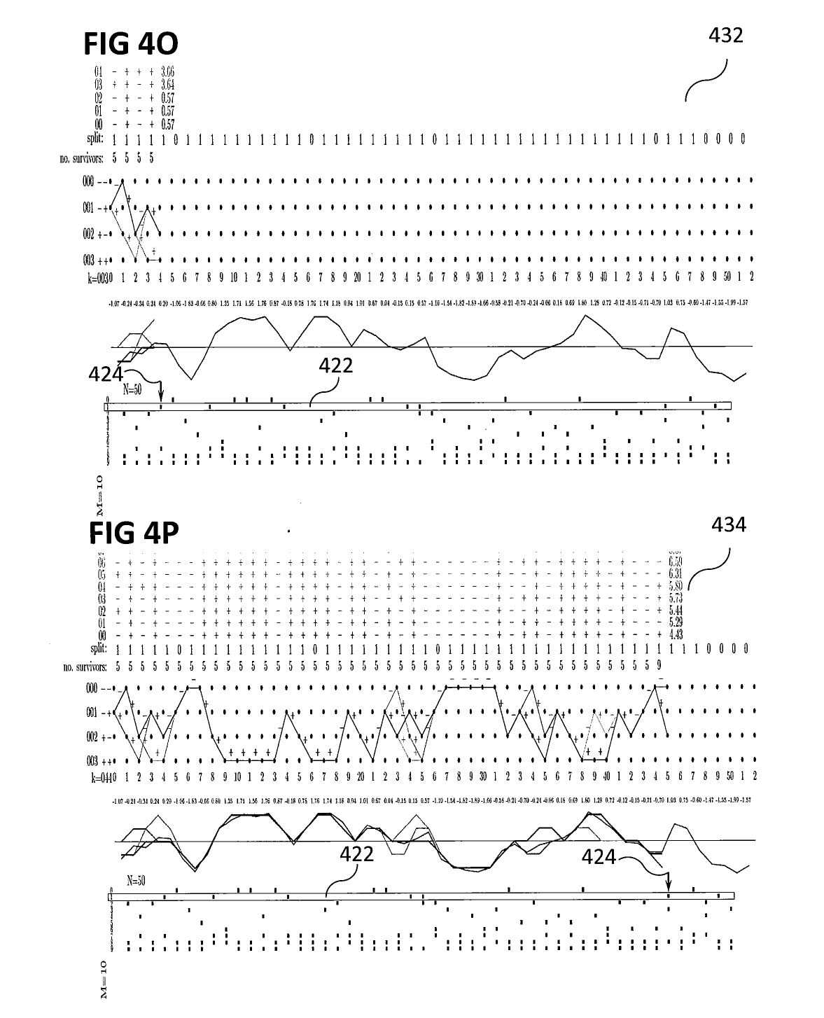

The minimum metric sequence returned by the VA (Viterbi algorithm) is utilized by the second stage (multi-pass with splitting at parity check nodes) in MP-JVDD. According to various embodiments, a parity check matrix H, is an m×n matrix where m is the number of parity checks and n is the number of coded bits with each row corresponding to one of the m parity checks. In this context, the second stage of MP-JVDD checks for each of the m parity checks in turn. This is achieved by computing metrics (branch and path) metrics for each survivor evolving from a node that is involved in the current parity check constraint. In other words, the incoming survivors to a parity check node is split into 2 new survivors. Then, this set of survivors may be restricted based on the comparison of the survivors' metric with a threshold or by retaining only a certain predefined number of competing survivors. In this way, survivors are propagated down the trellis by splitting and then curtailing their numbers either via the comparison of their metric to a predetermined threshold, or cropping survivors more than a certain limit. The retained survivors are then checked for parity and discards survivors that fail the syndrome check, i.e., chᵢ^{T}=0. The evolution of the algorithm in trellis is illustrated in illustrations 400, 402, 404, 406, 408, 410, 412, 414, 416, 418, 420 of FIG. 4A to FIG. 4K.

The splitting and thresholding may be common for JVDD and MP-JVDD. However, the number and positioning of splits differentiates them and results in reduced complexity for MP-JVDD. In other words, MP-JVDD splits survivors only on nodes needed to get past each parity check in turn whereas JVDD splits survivors on all nodes. In this way, the MP-JVDD retains survivors that progressively make through each parity check. This can be better understood by referring to FIG. 4A to FIG. 4K, where the evolution of the trellis in MP-JVDD is shown. This process is then repeated at each row of the parity check matrix H to estimate the MMLC. The second stage of MP-JVDD is thereby processed multiple times until all the parity checks are satisfied. Thus, MP-JVDD finds and returns the minimum metric legal codeword (MMLC), i.e., the legal codeword that satisfies all the parity checks in H with the minimum metric.

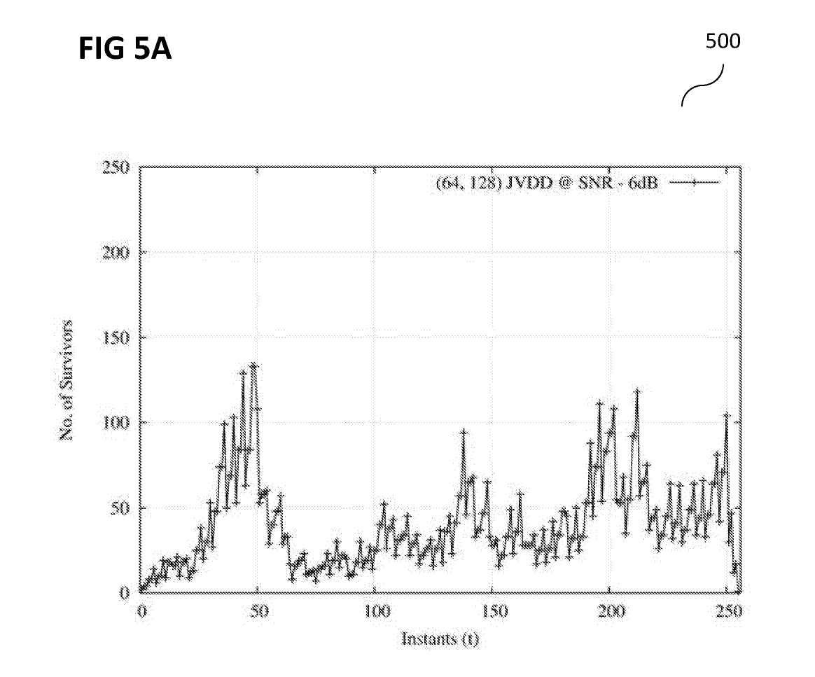

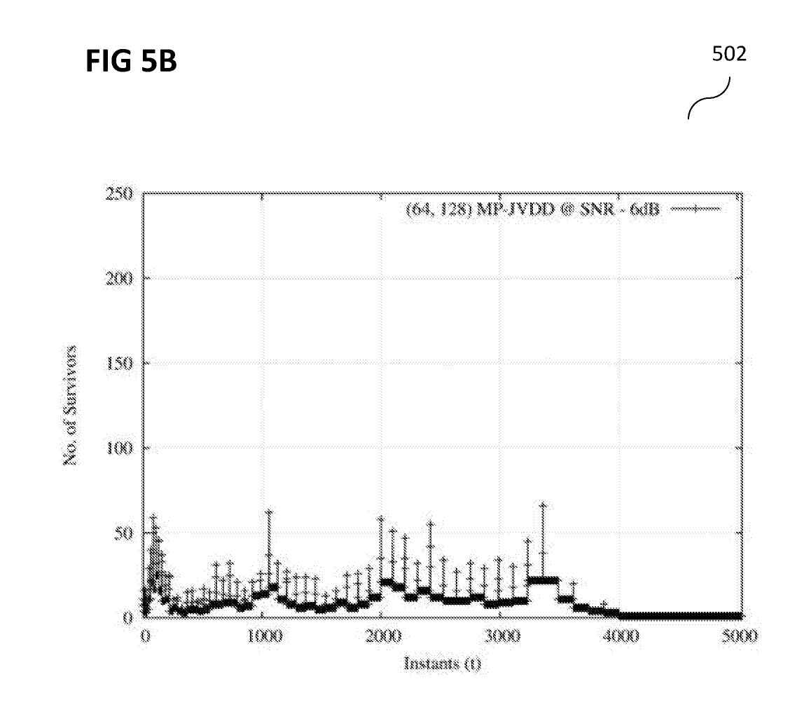

The reduction in number of survivors propagating through the trellis for MP-JVDD compared to JVDD is illustrated in illustrations 500 and 502 of FIG. 5A and FIG. 5B. FIG. 5A is related to JVDD, and FIG. 5B is related to MP-JVDD. According to various embodiments, a devised general framework for designing reduced complexity optimal maximum likelihood (ML) decoder may be provided. According to various embodiments, a much lower number of survivors in MP-JVDD compared to JVDD may be provided. According to various embodiments, more instances in MP-JVDD but uniqueness of splitting may guarantee reduced complexity at most instances.

However, it should be noted that the MP-JVDD similar to JVDD does not guarantee to return the MMLC, which is the optimal decision over a coded AWGN/ISI channel. The MP-JVDD could fail to return the MMLC if the MMLC path temporarily acquires a larger metric over a part of the trellis that causes it to be discarded during the threshold comparison with a competing path, performed at the second stage. Since the MP-JVDD is designed to return the MMLC, this is undesirable and the only way to prevent this is to use a larger threshold which results in greater computational complexity. However, the computational resources required for MP-JVDD will be lower compared to JVDD as the former utilizes only the minimum metric sequence obtained from the Viterbi algorithm to estimate the MMLC.

In the following, the class of codes utilized for MP-JVDD will be described.

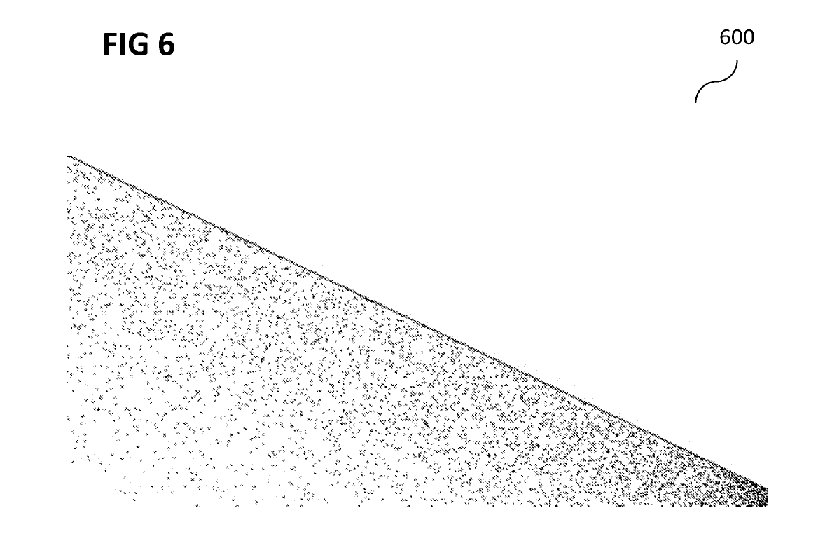

FIG. 6 shows an illustration 600 of the variable-gradient Gaussian distribution linear diagonal (VGGDLD) codes at a codeword length of 512. In this class of codes, in order to ensure splitting of survivors occurs at each nodes the parity check matrix is designed with a constant number of ones in each column (column weight). Further in order to evenly space the parity checks throughout the trellis a diagonal construction is designed where the gradient of the diagonal is controlled by two independent shift parameters, dx and dy. It is observed that increasing the parameter dx leads to increased number of survivors in the trellis as the parity checking gets shifted in the trellis, thus the optimum value is set to dx=0. However, the parameter dy has to be designed optimally. Too small a value leads to under-protected bits at the end of the codeword, and too large a value reduces the number of parity checks which increases the complexity of the trellis.

The relative performance of MP-JVDD and JVDD employing this class of codes and the effectiveness of MP-JVDD in lowering the computational complexity is described below in more detail.

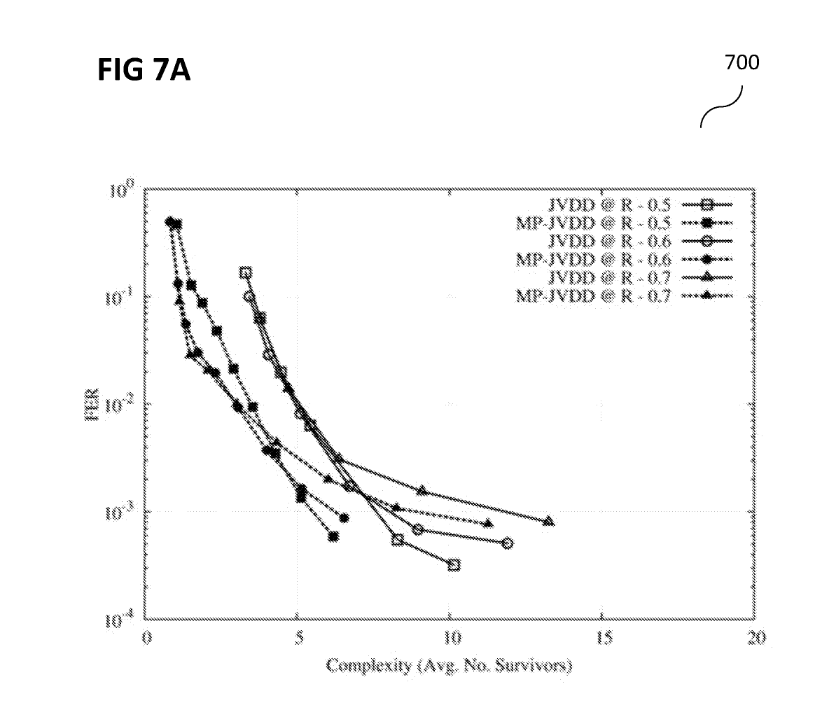

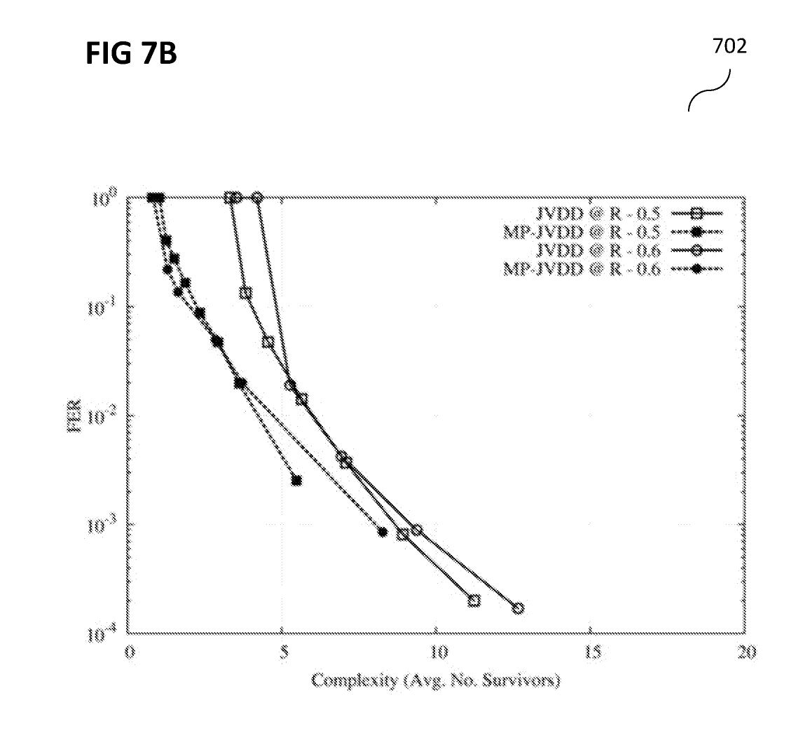

FIG. 7A and FIG. 7B show illustrations 700 and 702 of the variation of frame error rate (FER) with complexity for MP-JVDD and JVDD (with VGGDLD codes) at different rates for short codeword lengths (CWL) of 64 (FIG. 7A) and 128 (FIG. 7B), with a SNR (signal to noise ratio) of 8 dB. The complexity is measured as the average number of survivors in the MP-JVDD and JVDD trellis, respectively. It is observed that the complexity increases with code-rate for both JVDD and MP-JVDD. Lowering the code-rate is expected to reduce errors in any channel at the cost of increased coding overhead through the increased number of parity check bits. Further, it shows that MP-JVDD outperforms JVDD at all rates due to the lower number of survivors propagating through the MP-JVDD trellis. Thus, it can be seen that complexity increases with rate, and that MP-JVDD outperforms JVDD at all rates.

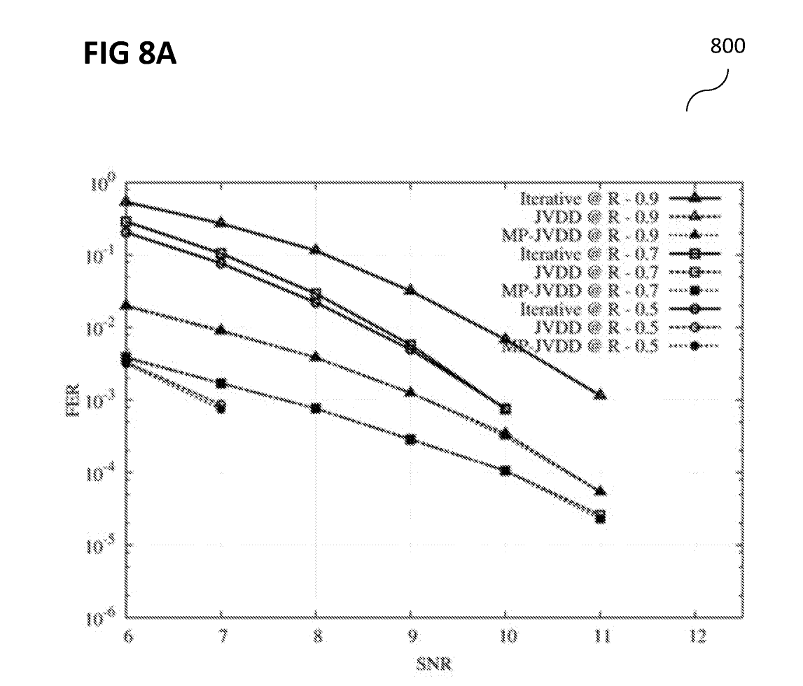

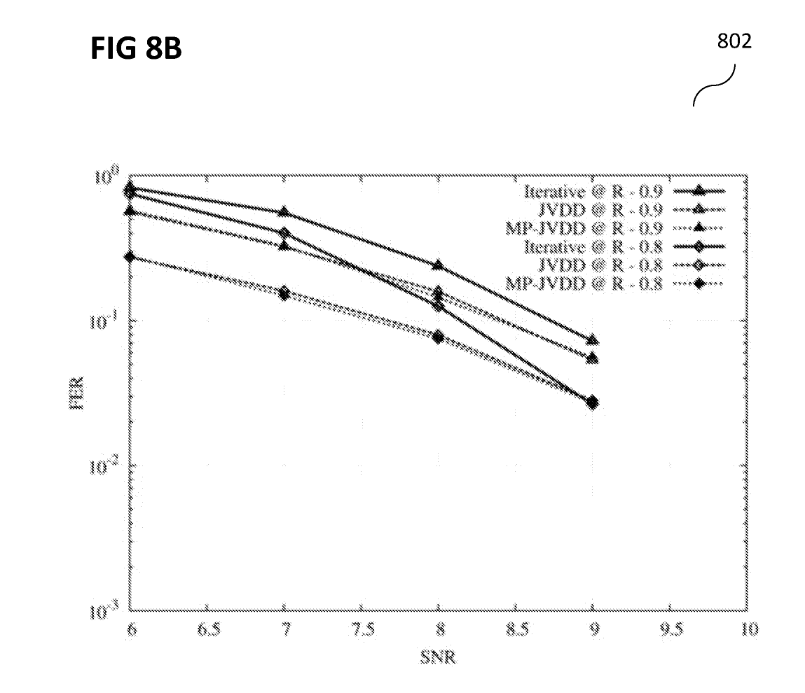

FIG. 8A and FIG. 8B show illustrations 800 and 802 of iterative detector, MP-JVDD and JVDD results for VGGDLD codes. Solid lines correspond to JVDD while dotted curves correspond to MP-JVDD with the same pointer. The code-rate along with the signal-to-noise ratio (SNR) is varied for all cases at codeword lengths 64 (FIG. 8A, Column weight of codes=5) and 128 (FIG. 8B, Column weight of codes=10). It will be understood that “column weight” refers to the number of ones in a column of the parity check matrix.

The performance of the iterative BCJR/SPA detector with 5 iterations is shown in FIG. 8A and FIG. 8B for reference. It is observed that both JVDD and MP-JVDD outperforms the iterative detector/decoder by around 2 dB. Further, it is observed that MP-JVDD achieves similar performance of JVDD. In other words, reduced complexity of MP-JVDD is achieved without any performance loss.

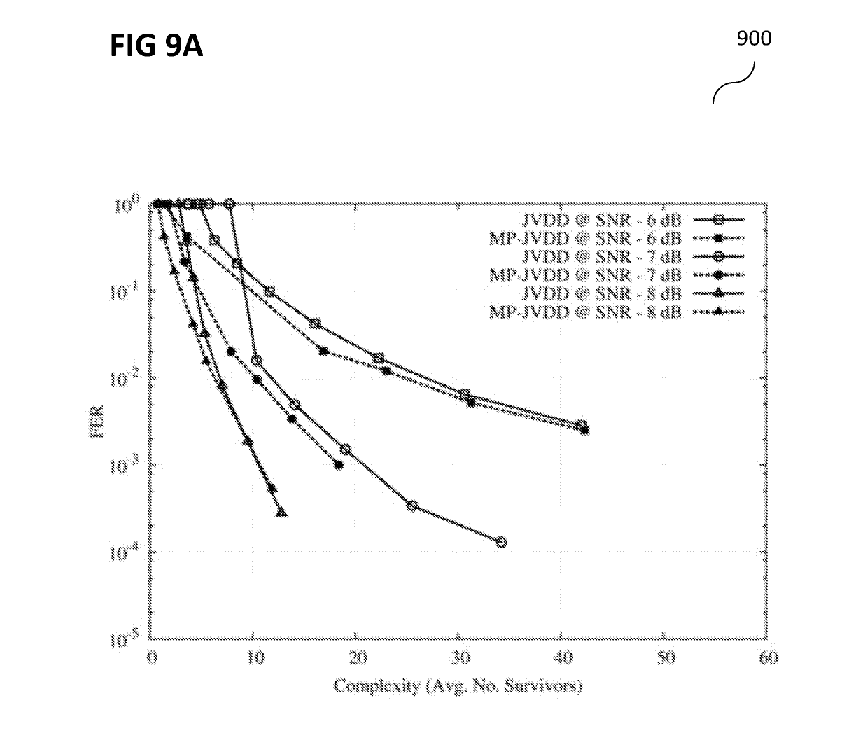

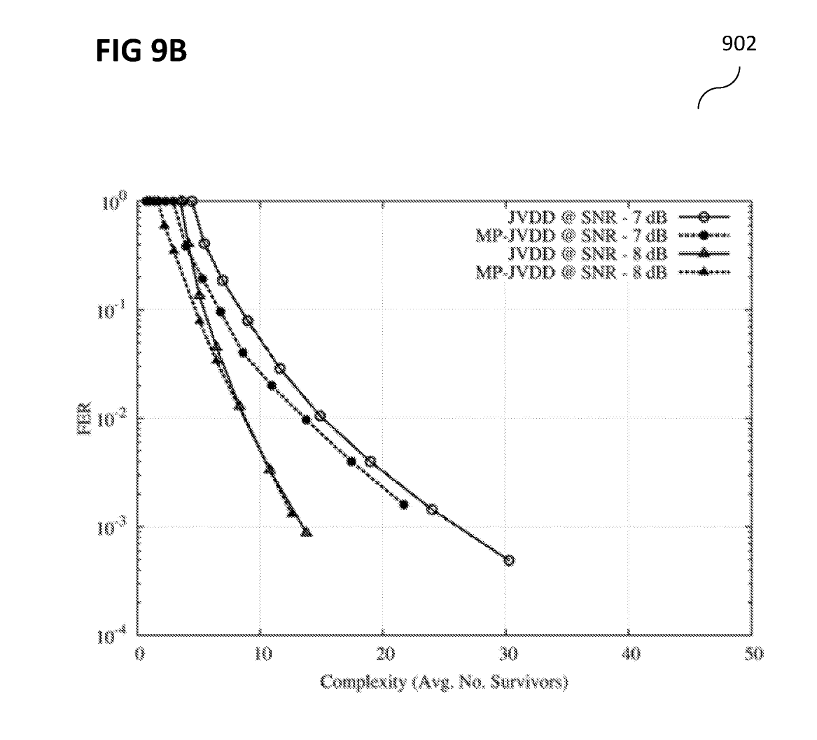

FIG. 9A and FIG. 9B show illustrations 900 and 902 of the variation of frame error rate (FER) with complexity for MP-JVDD and JVDD at different SNRs for intermediate codeword lengths (CWLs) of 256 (FIG. 9A, R=0.6) and 512 (FIG. 9B, R=0.5), for VGGDLD codes. It is observed that complexity decreases with increasing SNR as there are less distortions from the channel, which lowers the probability of deviating from the correct path in the trellis. This results in fewer survivors and reduced complexity. Further, the reduced complexity offered by MP-JVDD is also observed at all SNRs.

The computational complexity of JVDD may increase with code-rate and may decrease with increasing SNR.

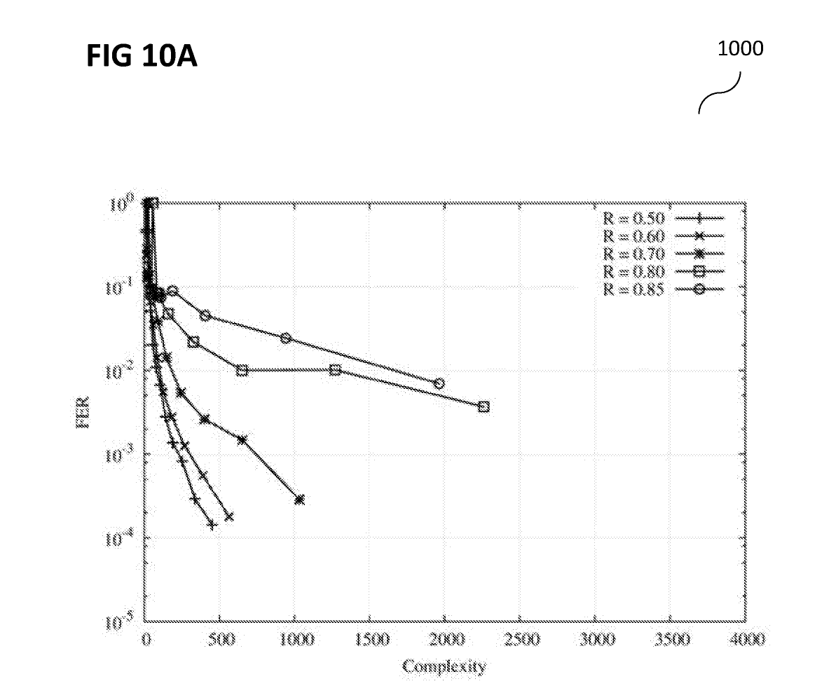

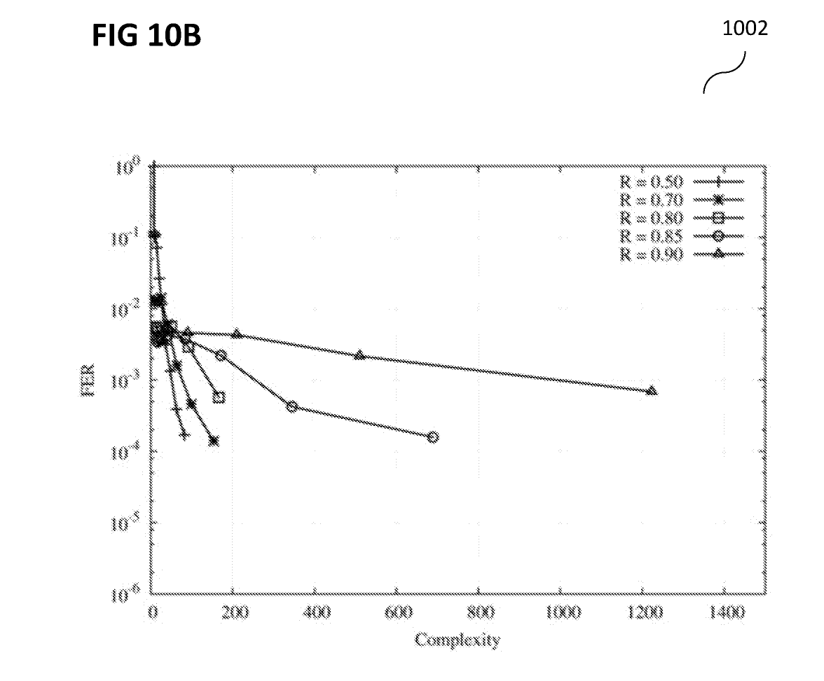

FIG. 10A and FIG. 10B show illustrations 1000 and 1002 of FER comparisons with complexity of JVDD algorithm at different rates. There may be a large number of survivors in trellis, which may lead to increased memory requirements.

The MP-JVDD according to various embodiments may operate on a trellis and may have two-stage decoding process. The Viterbi algorithm may compute a minimum metric sequence and might not return minimum metric legal codeword (MMLC). Multi-pass with splitting at parity check nodes according to various embodiments may split survivors only on nodes needed to get past each parity check in turn. Uniqueness of splitting may be ensured (splitting occurs only if that parity check node is not involved in any previous checks). Survivors whose metrics is smaller than threshold may be retained (which may further reduce complexity). Survivors where metric>(is greater than) Min. metric+(plus) threshold may be discarded.

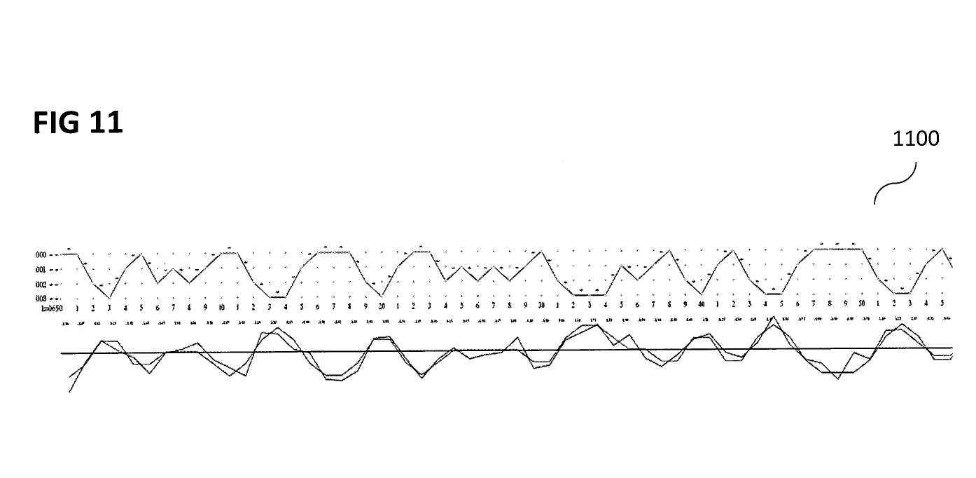

FIG. 11 shows an illustration 1100 of an output of Viterbi algorithm. A maximum likelihood sequence detection may provide a minimum metric sequence. Each state may have one survivor path corresponding to a most likely path. A minimum metric sequence might not be a minimum metric legal codeword (MMLC).

According to various embodiments, a multi-pass with splitting at parity check nodes may be provided. It may be attempted to return minimum metric legal codeword (MMLC), which may provide an optimal decision for coded AWGN/ISI channel. According to various embodiments, split of survivors may be needed only on parity check nodes to get past each parity check in turn.

According to various embodiments, the following parity check constraint (in other words: parity check criterion) may be considered:

[ĉ₁h₁⁽¹⁾+ĉ₂h₂⁽¹⁾+\textcircled{c}₃h₃⁽¹⁾+ĉ₄h₄⁽¹⁾]₂=0 (1)

where [·] ₂ denotes modular-2 operation.

According to various embodiments, split of each incoming survivor path to parity check nodes 1, 2, 3 and 4 may be required to satisfy parity check constraint (1)Repeat for parity checks 2, 3, . . . , m.

According to various embodiments, MP-JVDD may return MMLC that satisfies syndrome check, ĉH^{T}=0.

As described above, FIG. 4A to FIG. 4K show illustrations 400, 402, 404, 406, 408, 410, 412, 414, 416, 418, 420 of multi-pass with splitting at parity check nodes, wherein Parity Check Row (5)=[7, 19, 33, 35, 37], Threshold=4.

FIG. 4LA to FIG. 4P show illustrations 426, 428, 430, 432, and 434 of multi-pass with splitting at parity check nodes, wherein Parity Check Row (1)=[4, 8, 14, 24, 25, 45, 49], Threshold=4.

In FIG. 4A to FIG. 4P, boxes 422 illustrate the current parity constraint which the MP-JVDD algorithm is checking and arrows 424 corresponds to a 1 in the parity check constraint or the parity check node where splitting occurs in the MP-JVDD trellis.

According to various embodiments, splitting of survivors at every node may be ensured. Parity checking constraint considers all node positions.

According to various embodiments, parity check matrix (H) may be designed with constant number of ones in column (column weight) placed according to Gaussian distribution below the main diagonal. Evenly spaced parity check nodes may be provided by ensuring splitting occurs at every nodes at least once.

FIG. 6 shows an illustration of variable-gradient Gaussian distribution linear diagonal (VGGDLD) codes at R=0.5 and CWL=512.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A joint detector/decoder device comprising:
an input circuit configured to receive an input signal;
a splitting determination circuit configured to determine whether a survivor is to be split based on a parity check criterion; and
a survivor splitting circuit configured to produce a plurality of survivors of a next instance based on at least one survivor of a previous instance and based on the input signal, if it is determined that the survivor of the previous instance is to be split;
wherein each survivor has an associated bit sequence.

2. The joint detector/decoder device of claim 1, further comprising:
a survivor discarding circuit configured to discard survivors based on a set of predetermined criteria.

3. The joint detector/decoder device of claim 2,
wherein a survivor determination circuit comprising the survivor splitting circuit and the survivor discarding circuit is configured to determine that a survivor survives to the next instance if a metric of the survivor is within a pre-determined metric threshold.

4. The joint detector/decoder device of claim 1,
wherein the joint detector/decoder device is further configured to retain a predetermined set of survivors with smallest metrics as the plurality of survivors of the next instance.

5. The joint detector/decoder device of claim 1,
wherein the parity check criterion comprises a parity check based on whether the survivor's bit pattern satisfies the checks of a parity check matrix.

6. The joint detector/decoder device of claim 5,
wherein the parity check matrix comprises a matrix with entries of zero above a pre-determined sub-diagonal of the parity check matrix.

7. The joint detector/decoder device of claim 3,
wherein the metric comprises an Euclidean metric.

8. A joint detection/decoding method comprising:
receiving an input signal;
determining whether a survivor is to be split based on a parity check criterion; and
producing a plurality of survivors of a next instance based on at least one survivor of a previous instance and based on the input signal, if it is determined that the survivor of the previous instance is to be split;
wherein each survivor has an associated bit sequence.

9. The joint detection/decoding method of claim 8, further comprising
discarding survivors based on a set of predetermined criteria;

10. The joint detection/decoding method of claim 8, further comprising
determining that a survivor survives to the next instance if a metric of the survivor is within a pre-determined metric threshold.

11. The joint detection/decoding method of claim 8, further comprising:
retaining a predetermined number of survivors with smallest metrics as the plurality of survivors of the next instance.

12. The joint detection/decoding method of claim 8,
wherein the pre-determined validity criterion comprises a parity check based on whether the survivor's bit pattern satisfies the checks of a parity check matrix.

13. The joint detection/decoding method of claim 12,
wherein the parity check matrix comprises a matrix with entries of zero above a pre-determined sub-diagonal of the parity check matrix.

14. The joint detection/decoding method of claim 8, further comprising:
determining, during a metric thresholding section, whether a survivor carries on to the next instance based on a metric of the bit sequence and independent from whether the bit sequence fulfills a pre-determined validity criterion.

15. The joint detection/decoding method of claim 14, further comprising:
determining, during a parity check section, whether a survivor carries on to the next instance based on a metric of the bit sequence and based on whether the bit sequence fulfills a pre-determined validity criterion.

16. The joint detection/decoding method of claim 9,
wherein a metric comprises an Euclidean metric.
